(19) United States
(12) Patent Application Publication
(10) Pub. No.: US 2008/0062740 A1
(43) Pub. Date: Mar. 13, 2008

(54) Methods of programming a resistive memory device

(76) Inventors: In-Gyu Baek, Seoul (KR); Jang-Eun Lee, Gyeonggi-do (KR); Se-Chung Oh, Gyeonggi-do (KR); Kyung-Tae Nam, Gyeonggi-do (KR); Jun-Ho Jeong, Gyeonggi-do (KR); Eun-Kyung Yim, Daegu (KR)

Correspondence Address: MYERS BIGEL SIBLEY & SAJOVEC, PO BOX 37428, RALEIGH, NC, 27627, US

(21) Appl. No.: 11/895,371

(22) Filed: Aug. 24, 2007

(30) Foreign Application Priority Data
Aug. 28, 2006 (KR) 2006-081617

(51) Int. Cl. G11C 11/00

(52) U.S. Cl. 365/148

(57) ABSTRACT

Methods of programming a RRAM device are provided. An increasing set current is applied to a data storing layer pattern of the RRAM device while measuring a resistance of the data storing layer pattern until the resistance indicates a set state in the data storing layer pattern. An increasing reset voltage is applied to the data storing layer pattern of the RRAM device while measuring the resistance of the data storing layer pattern until the resistance indicates a reset state in the data storing layer pattern.

### CROSS-REFERENCE TO RELATED APPLICATION

This application is related to and claims priority under 35 USC § 119 from Korean Patent Application No. 2006-81617 filed on Aug. 28, 2006 in the Korean Intellectual Property Office, the disclosure of which is incorporated herein by reference in its entirety.

### BACKGROUND OF THE INVENTION

The present invention relate to methods of programming a memory, and more particularly, to methods of programming a resistive memory device in which data is programmed in accordance with changes in resistance of a data storing layer.

Generally, stored data in non-volatile memory devices remains intact even when a power source is cut off. Non-volatile memory devices are used, for example, in computers, mobile communication terminals, memory cards and the like.

Flash memory devices are one type of non-volatile memory device. A flash memory device typically includes memory cells having stacked gate structures. Each of the stacked gate structures generally includes a tunnel insulation layer, a floating gate, a dielectric layer, and a control gate electrode. The flash memory device may have relatively high cell reliability and improved efficiency in programming when the tunnel insulation layer has a high quality and the cell has an increased coupling ratio.

Research on developing new types of non-volatile memory devices continues. For example, this research includes developing non-volatile memory devices using a material layer having a resistance that may be reversibly changed by electric pulses as a data storing layer. These non-volatile memory devices may have an improved level (density) of integration compared to memory devices using a capacitor as a data storing layer, where the data storing capacity is generally determined by a size of the capacitor.

An example of another type of non-volatile memory device is a phase-change memory device (PRAM) that uses a phase-change material layer reversibly changed from an amorphous state to a crystalline state by an applied electric pulse. A further example is a resistive random access memory (RRAM) device that uses a variable resistive material layer as a data storing layer. The variable resistive material layer has a reversible resistance change according to a polarity and/or a magnitude of an applied electric pulse. The variable resistive material layer may include a colossal magneto resistive (CMR) material layer, such as a Pr₁₋ₓCaₓMnO₃(PCMO) layer. However, forming the PCMO layer to have a uniform crystalline structure on an entire wafer is generally difficult, and the PCMO layer may not be easily patterned using a photolithography process. Thus, using the PCMO layer in memory devices may be difficult.

Still another example of a new type of the non-volatile memory device is a RRAM device using a binary metal oxide layer as a data storing layer. The binary metal oxide layer has a resistance change when a conductive filament is generated or extinguished by an electric pulse.

A method of programming a RRAM device using the binary metal oxide layer as a data storing layer is described as follows. An electric pulse having a magnitude above a first critical value is applied to a data storing layer to generate a conductive filament in the data storing layer so that a set state may be programmed in a RRAM device. Thus, resistance of the data storing layer may be decreased below a reference resistance by the generated conductive filament(s). Furthermore, an electric pulse having a magnitude above a second critical value is applied to the data storing layer to extinguish (remove) the conductive filament in the data storing layer so that a reset state may be programmed in the RRAM device. Thus, resistance of the data storing layer may be increased above a reference resistance by the generated conductive filament and returned to the reference resistance level.

When an electric pulse is applied to the data storing layer to generate conductive filaments and, thus, to program the RRAM device, a single pulse having a constant current is usually applied to each of the memory cells. However, when the single pulse is applied to each of the memory cells, the conductive filaments may be sufficiently generated in some of the memory cells and may not be sufficiently generated in others of the memory cells because each of the memory cells generally does not have the same set switching characteristics. The memory cells without sufficient conductive filaments may have a very high set resistance.

Thus, an electric pulse having a sufficiently high current is typically applied to the memory cells in order that set switching may be generated to sufficiently decrease the set resistance of all cells. However, when the electric pulse having the high current is applied to the memory cells, a reset resistance may be decreased to a very low value. Additionally, currents in a reset state are typically increased so that an increased amount of power may be consumed. Thus, stably programming a RRAM device may be difficult and result in generating a resistance distribution of memory cells in a set state and a reset state.

### SUMMARY OF THE INVENTION

Embodiments of the present invention include methods of programming a RRAM device. An increasing set current is applied to a data storing layer pattern of the RRAM device while measuring a resistance of the data storing layer pattern until the resistance indicates a set state in the data storing layer pattern. An increasing reset voltage is applied to the data storing layer pattern of the RRAM device while measuring the resistance of the data storing layer pattern until the resistance indicates a reset state in the data storing layer pattern.

In further embodiments, applying an increasing set current comprises repeatedly alternately applying a set current pulse and a first electric pulse, wherein the set current pulse decreases resistance of the data storing layer pattern and the resistance of the data storing layer pattern is measured by the first electric pulse and wherein the set current pulse has an increased current each time it is applied. Applying an increasing reset voltage comprises repeatedly alternately applying a reset voltage pulse and a second electric pulse, wherein the reset voltage pulse increases the resistance of the data storing layer pattern and the resistance of the data storing layer pattern is measured by the second electric pulse and wherein the reset voltage pulse has an increased voltage each time it is applied.

In other embodiments, applying an increasing set current further includes stopping applying the set current pulse to the data storing layer pattern when the measured resistance of the data storing layer pattern is lower than a first reference resistance. Applying an increasing reset voltage may further include stopping applying the reset voltage pulse to the data storing layer pattern when the measured resistance of the data storing layer pattern is higher than a second reference resistance. The reset voltage pulse may have a width greater than that of the set current pulse. The set current pulse may be a plurality of pulses. The first and the second electric pulses may be a current pulse and/or a voltage pulse. The data storing layer pattern may be a binary metal oxide.

In other embodiments, applying an increasing set current and applying an increasing reset voltage are carried out on each of a plurality of memory cells defined by a data storing layer pattern. Each of the respective memory cells has the set current and/or reset voltage increased to a level corresponding to a characteristic of the respective memory cell.

In further embodiments, applying an increasing set current comprises gradually increasing the set current applied to the data storing layer pattern until the resistance of the data storing layer pattern is lower than a first reference resistance. Applying an increasing reset voltage comprises gradually decreasing the reset voltage applied to the data storing layer pattern until the resistance of the data storing layer pattern is higher than a second reference resistance.

In yet other embodiments, applying an increasing set current includes measuring the resistance of the data storing layer pattern when the set current is increased, the resistance being changed responsive to the set current, and stopping applying the set current to the data storing layer pattern when the measured resistance of the data storing layer pattern is lower than the first reference resistance. Applying an increasing reset voltage may include measuring the resistance of the data storing layer pattern when the reset voltage is increased, the resistance being changed responsive to the reset voltage, and stopping applying the reset voltage to the data storing layer pattern when the measured resistance of the data storing layer pattern is higher than the second reference resistance. The resistance of the data storing layer pattern may be measured by detecting a voltage of both ends of the data storing layer pattern and/or by detecting a current flowing through the data storing layer pattern.

In further embodiments, applying an increasing set current includes: (a) applying an n-th set current pulse to the data storing layer pattern, the n-th set current pulse decreasing resistance of the data storing layer pattern; (b) determining whether the resistance of the data storing layer pattern is lower than a first reference resistance; (c) applying a (n+1)-th set current pulse to the data storing layer pattern when the resistance of the data storing layer pattern is higher than the first reference resistance, the (n+1)-th set current pulse having a current higher than that of the n-th set current pulse; (d) repeatedly performing steps (a) to (c) until the resistance of the data storing layer pattern is lower than the first reference resistance; and (e) stopping applying the set current pulse to the data storing layer pattern when the resistance of the data storing layer pattern is lower than the first reference resistance. Applying an increasing reset voltage includes: (f) applying an m-th reset voltage pulse to the data storing layer pattern, the m-th reset voltage pulse increasing the resistance of the data storing layer pattern; (g) determining whether the resistance of the data storing layer pattern is higher than a second reference resistance; (h) applying a (m+1)-th reset voltage pulse to the data storing layer pattern when the resistance of the data storing layer pattern is lower than the second reference resistance, the (m+1)-th reset voltage pulse having a voltage higher than that of the m-th reset voltage pulse; (i) repeatedly performing steps (f) to (h) until the resistance of the data storing layer pattern is higher than the second reference resistance; and (j) stopping applying the reset voltage pulse to the data storing layer pattern when the resistance of the data storing layer pattern is higher than the second reference resistance, wherein n and m are positive integers. An electric pulse may be applied for reading resistance to the data storing layer pattern, wherein the resistance of the data storing layer pattern is measured by the electric pulse for reading resistance.

In yet further embodiments, methods of programming a RRAM device include programming a set state and a reset state in a data storing layer pattern. Programming the set state in the data storing layer pattern includes alternately applying an n-th set current pulse and a first electric pulse for reading resistance, wherein the n-th set current pulse decreases resistance of the data storing layer pattern, and wherein the resistance of the data storing layer pattern is measured by the first electric pulse for reading resistance. Programming the reset state in the data storing layer pattern includes alternately applying an m-th reset voltage pulse and a second electric pulse for reading, wherein the m-th set voltage pulse increases the resistance of the data storing layer pattern, and wherein the resistance of the data storing layer pattern is measured by the second electric pulse for reading resistance, wherein n and m are positive integers.

In other embodiments, when the measured resistance of the data storing layer pattern is higher than a first reference resistance, programming the set state in the data storing layer pattern further includes: (a) applying a (n+1)-th set current pulse to the data storing layer pattern, the (n+1)-th set current pulse configured to have a current higher than that of the n-th set current pulse; (b) applying the first electric pulse for reading resistance to the data storing layer pattern; and (c) repeatedly performing steps (a) and (b) until the resistance of the data storing layer pattern is lower than the first reference resistance. Programming the reset state in the data storing layer pattern may further include stopping applying the m-th reset voltage pulse to the data storing layer pattern when the measured resistance of the data storing layer pattern is higher than a second reference resistance.

In yet further embodiments when the measured resistance of the data storing layer pattern is lower than a second reference resistance, programming the reset state in the data storing layer pattern further includes: (a) applying a (m+1)-th reset voltage pulse to the data storing layer pattern, the (m+1)-th reset voltage pulse configured to have a voltage higher than that of the m-th reset voltage pulse; (b) applying the second electric pulse for reading resistance to the data storing layer pattern; and (c) repeatedly performing steps (a) and (b) until the resistance of the data storing layer pattern is higher than the second reference resistance.

In other embodiments, methods of programming a RRAM device include programming a set state and a reset state in a data storing layer. Programming the set state in a data storing layer pattern includes gradually increasing a set current and applying the set current to the data storing layer pattern until the resistance of the data storing layer pattern is lower than a first reference resistance. Programming the reset state in the data storing layer pattern includes gradually decreasing a reset voltage and applying the reset voltage to the data storing layer pattern until the resistance of the data storing layer pattern is higher than a second reference resistance.

### BRIEF DESCRIPTION OF THE DRAWINGS

The above and other features and advantages of the present invention will become more apparent by describing in detail exemplary embodiments thereof with reference to the accompanying drawings, in which:

FIG. 1 is a cross-sectional view illustrating a unit cell of a RRAM device in accordance with some embodiments of the present invention;

FIG. 2 is a flow chart illustrating a method of programming a set state in a RRAM device in accordance with some embodiments of the present invention;

FIG. 3 is a timing diagram of electric pulses applied to a data storing layer pattern illustrating the method of programming the set state in an RRAM device in accordance with some embodiments of the present invention;

FIG. 4 is a graph illustrating relationships between voltages and currents of two unit cells having different critical current values when a set current pulse is continuously applied to the unit cells by some embodiments of the method of FIG. 2;

FIG. 5 is a flow chart illustrating a method of programming a reset state in a RRAM device in accordance with some embodiments of the present invention;

FIG. 6 is a timing diagram of electric pulses applied to a data storing layer pattern illustrating the method of programming the reset state in a RRAM device in accordance with some embodiments of the present invention;

FIG. 7 is a graph illustrating relationships between voltages and currents of two unit cells having different critical voltage values when a reset voltage pulse is continuously applied to the unit cells by some embodiments of the method of FIG. 5;

FIG. 8 is a flow chart illustrating a method of programming a set state in a RRAM device in accordance with other embodiments of the present invention;

FIG. 9 is a graph illustrating resistance of a data storing layer pattern when a set state is programmed in a unit cell by some embodiments of the method of FIG. 8;

FIG. 10 is a flow chart illustrating a method of programming a reset state in a RRAM device in accordance with other embodiments of the present invention; and

FIG. 11 is a graph illustrating resistance of a data storing layer pattern when a reset state is programmed in a unit cell by some embodiments of the method of FIG. 10.

### DESCRIPTION OF THE EMBODIMENTS

The present invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

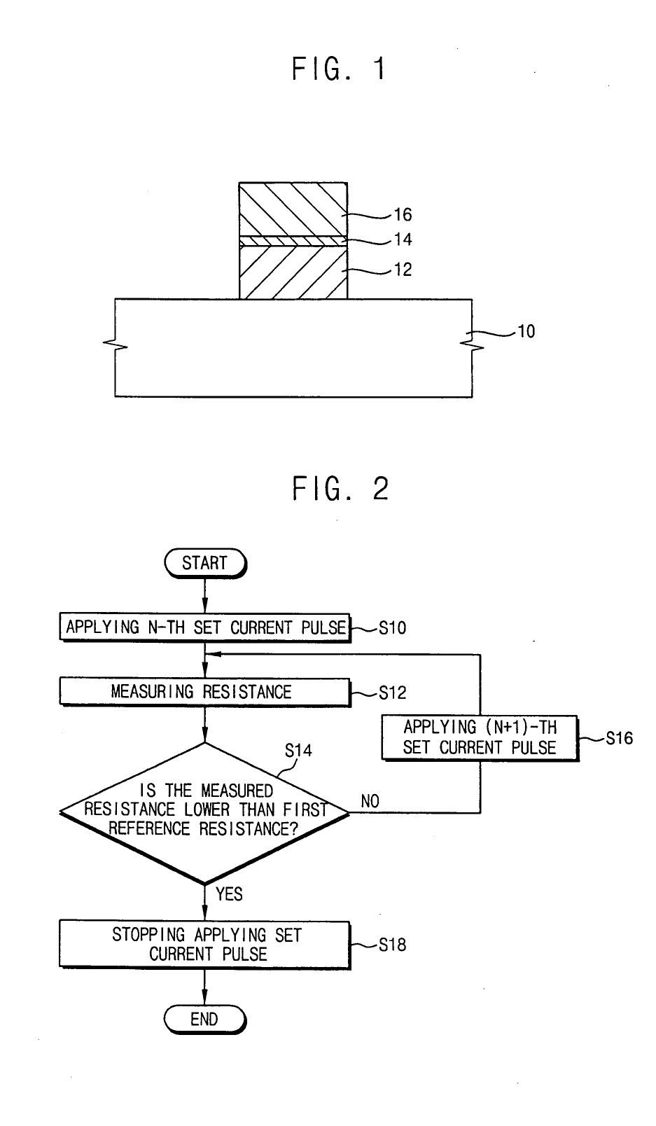

Hereinafter, the present invention will be explained in detail with reference to the accompanying drawings. FIG. 1 is a cross-sectional view illustrating a unit cell of a RRAM device in accordance with some embodiments of the present invention. Referring to FIG. 1, a first electrode 12 is formed on a substrate 10. The substrate 10 may include a semiconductor substrate, such as a silicon substrate, a silicon-on-insulator substrate and/or the like. In some embodiments, the substrate 10 may include a flexible substrate such as an inorganic substrate, organic substrate and/or the like. The inorganic substrate may include glass, and the organic substrate may include a stable organic material. The first electrode 12 may serve as a lower electrode in the RRAM device.

The first electrode 12 may include a conductive material, such as a metal, a metal nitride, a metal oxide and/or a doped semiconductor material. These may be used alone or in a combination thereof. In some embodiments of the present invention, the first electrode 12 includes a metal or a metal nitride.

Examples of the first electrode 12 may include aluminum (Al), copper (Cu), titanium nitride (TiN), titanium aluminum nitride (TiₓAl_{y}N_{z}), iridium (Ir), platinum (Pt), silver (Ag), gold (Au), polysilicon, tungsten (W), titanium (Ti), tantalum (Ta), tantalum nitride (TaN), tungsten nitride (WN), nickel (Ni), cobalt (Co), chrome (Cr), stibium (Sb), iron (Fe), molybdenum (Mo), palladium (Pd), stannum (Sn), zirconium (Zr), zinc (Zn), iridium dioxide (IrO₂), strontium zirconate (SrZrO₃) and/or the like. These may be used alone or in a combination thereof.

The first electrode 12 may make contact with a plug (not shown) on the substrate 10. The first electrode 12 may be electrically connected to an impurity region (not shown) of a transistor on the substrate 10.

A data storing layer pattern 14 is formed on the first electrode 12. The data storing layer pattern 14 may include a material having a resistance that may be changed responsive to an electric pulse applied thereto. The data storing layer pattern 14 may include a binary metal oxide layer. Examples of a binary metal oxide layer include nickel oxide, niobium oxide, titanium oxide, zirconium oxide, hafnium oxide, cobalt oxide, iron oxide, copper oxide, zinc oxide, chrome oxide and/or the like. These may be used alone or in a combination thereof.

A second electrode 16 as an upper electrode is formed on the data storing layer pattern 14. The second electrode 16 may include a conductive material, such as a metal, a metal nitride, a metal oxide and/or a doped semiconductor material. These may be used alone or in a combination thereof. In some embodiments of the present invention, the second electrode 16 includes a metal or a metal nitride.

Examples of the second electrode 16 may include aluminum (Al), copper (Cu), titanium nitride (TiN), titanium aluminum nitride (TiₓAl_{y}N_{z}), iridium (Ir), platinum (Pt), silver (Ag), gold (Au), polysilicon, tungsten (W), titanium (Ti), tantalum (Ta), tantalum nitride (TaN), tungsten nitride (WN), nickel (Ni), cobalt (Co), chrome (Cr), stibium (Sb), iron (Fe), molybdenum (Mo), palladium (Pd), stannum (Sn), zirconium (Zr), zinc (Zn), iridium dioxide (IrO₂), strontium zirconate (SrZrO₃) and/or the like. These may be used alone or in a combination thereof.

Data may be programmed in the data storing layer pattern 14 by changing the resistance of the data storing layer pattern 14 included in each cell. The data stored in the data storing layer pattern 14 may be read by detecting a change of current or voltage according to the change of the resistance of the data storing layer pattern 14. The unit cells of the RRAM device may be disposed in a two dimensional array.

The unit cell of the RRAM device shown in FIG. 1 is illustrative in order to explain methods of programming a RRAM in accordance with some embodiments of the present invention, and the scope of the present invention is not limited to the RRAM device including the above unit cell.

Hereinafter, a method of programming a RRAM device in accordance with some embodiments of the present invention will be described. FIG. 2 is a flow chart illustrating a method of programming a set state in a RRAM device in accordance with some embodiments of the present invention. FIG. 3 is a timing diagram of electric pulses applied to a data storing layer pattern illustrating the method of programming the set state in the RRAM device. The method of programming the set state in the unit cell of the RRAM device in FIG. 1 will be explained with reference to FIGS. 2 and 3.

Referring to FIGS. 1 to 3, in block S10, a first set current pulse SET1 is applied to the data storing layer pattern 14 by means of the first electrode 12 or the second electrode 16. The first set current pulse SET1 is applied to the data storing layer pattern 14 so that current may flow from the first electrode 12 to the second electrode 16 through the data storing layer pattern 14 during a predetermined period. A conductive filament may be generated in the data storing layer pattern 14 by the first set current pulse SET1. In some embodiments, the first set current pulse SET1 is applied to the data storing layer pattern 14 so that current may flow from the second electrode 16 to the first electrode 12 through the data storing layer pattern 14 during a predetermined period.

The first set current pulse SET1 may be applied as a single pulse for about 1 ns to about 100 ns. In some embodiments, the first set current pulse SET1 may be applied using a plurality of pulses for about 1 ns to about 100 ns.

After applying the first set current pulse SET1 to the data storing layer pattern 14, in block S12, resistance of the data storing layer pattern 14 may be measured by applying a first electric pulse R1 for reading resistance to the data storing layer pattern 14. The first electric pulse R1 for reading resistance may include a current pulse or a voltage pulse. The first electric pulse R1 for reading resistance may include a current pulse having a lower current than that of the first set current pulse SET1 or a voltage pulse having a low voltage, more particularly, low enough so that a reset operation may not be performed by the voltage pulse.

When the current pulse serving as the first electric pulse R1 for reading resistance is applied to the data storing layer pattern 14, the resistance of the data storing layer pattern 14 may be measured by detecting a voltage across (or at each end of) the data storing layer pattern 14. When the voltage pulse serving as the first electric pulse R1 for reading resistance is applied to the data storing layer pattern 14, the resistance of the data storing layer pattern 14 may be measured by detecting a current flowing through the data storing layer pattern 14.

In block S14, it is determined whether the measured resistance of the data storing layer pattern 14 is lower than a reference resistance of a set state. When the measured resistance of the data storing layer pattern 14 is higher than the reference resistance, set switching may not have been sufficiently performed. When the measured resistance of the data storing layer pattern 14 is lower than the reference resistance, set switching may have been sufficiently performed so that the data storing layer pattern 14 has been programmed to be in a normal set state. When the measured resistance of the data storing layer pattern 14 is higher than the reference resistance, in block S16, a second set current pulse SET2 having a current higher than that of the first set current pulse SET1 is applied to the data storing layer pattern 14.

In block S12, resistance of the data storing layer pattern 14 may be measured again by applying a second electric pulse R2 for reading resistance to the data storing layer pattern 14.

The above-described processes may be repeated until measured resistance of the data storing layer pattern 14 is lower than the reference resistance by gradually increasing currents of set current pulses. For example, as shown in FIG. 3, a third set current pulse SET3 having a current higher than that of the second set current pulse SET2 is applied to the data storing layer pattern 14. Resistance of the data storing layer pattern 14 is measured by applying a third electric pulse R3 for reading resistance to the data storing layer pattern 14. When the measured resistance of the data storing layer pattern 14 is still higher than the reference resistance, a fourth set current pulse (not shown) having a current higher than that of the third set current pulse SET3 is applied to the data storing layer pattern 14. The above-mentioned processes may be repeated until measured resistance of the data storing layer pattern 14 is lower than the reference resistance.

When the measured resistance of the data storing layer pattern 14 is lower than the reference resistance, which means set switching has been sufficiently performed, set current pulses need no longer be applied to the data storing layer pattern 14 as indicated by block S18. Thus, a set state may be programmed in a unit cell of the RRAM device.

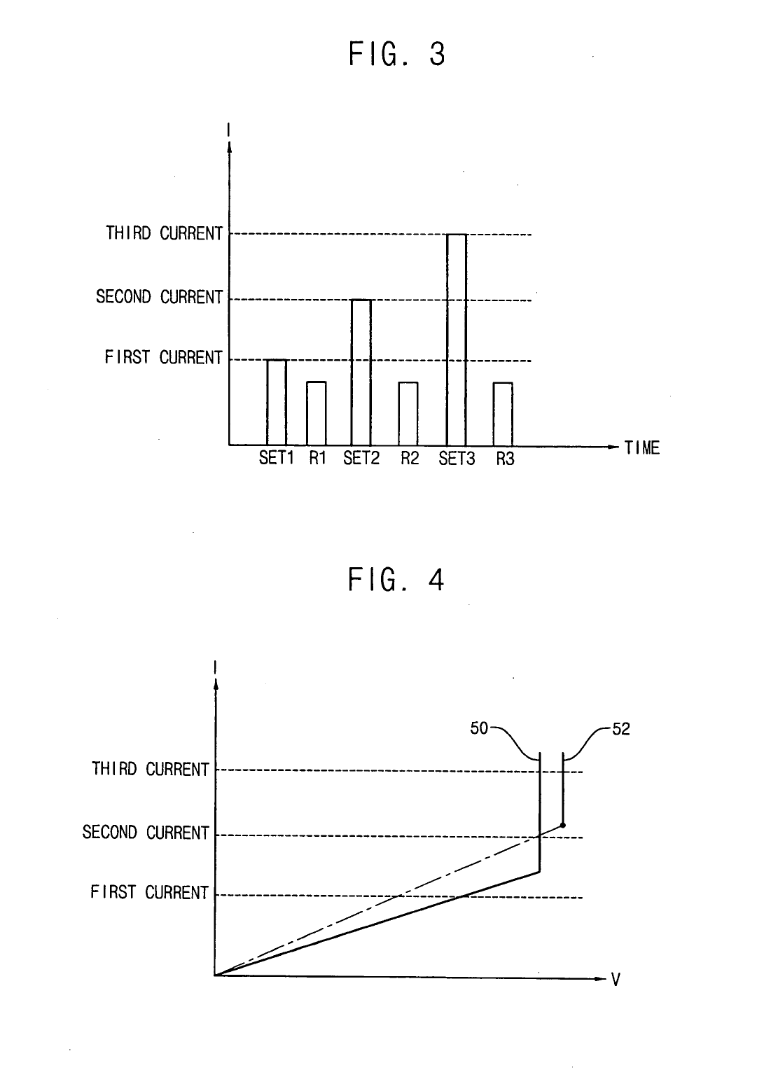

FIG. 4 is a graph illustrating exemplary relationships between voltages and currents of two unit cells having different critical current values when a set current pulse is continuously applied to the unit cells by the above-described method. Referring to FIG. 4, a set state may be programmed in the first unit cell 50 when the second set current pulse SET2 is applied, whereas the set state may be programmed in the second unit cell 52 when the third set current pulse SET3 is applied.

As illustrated above, a set state may be programmed in each of the unit cells of a RRAM so that the unit cells may have set resistances substantially the same as one another by gradually increasing currents in set current pulses and confirming whether or not set switching is sufficiently performed in each of the unit cells. Such a result may be provided even when the unit cells have wide distribution of critical current values.

Additionally, the set state may be programmed in each unit cell by applying a set current pulse having a minimum current value so that a minimum amount of conductive filaments for programming the set state may be generated. As such, the generated conductive filaments may be more easily removed when programming a reset state.

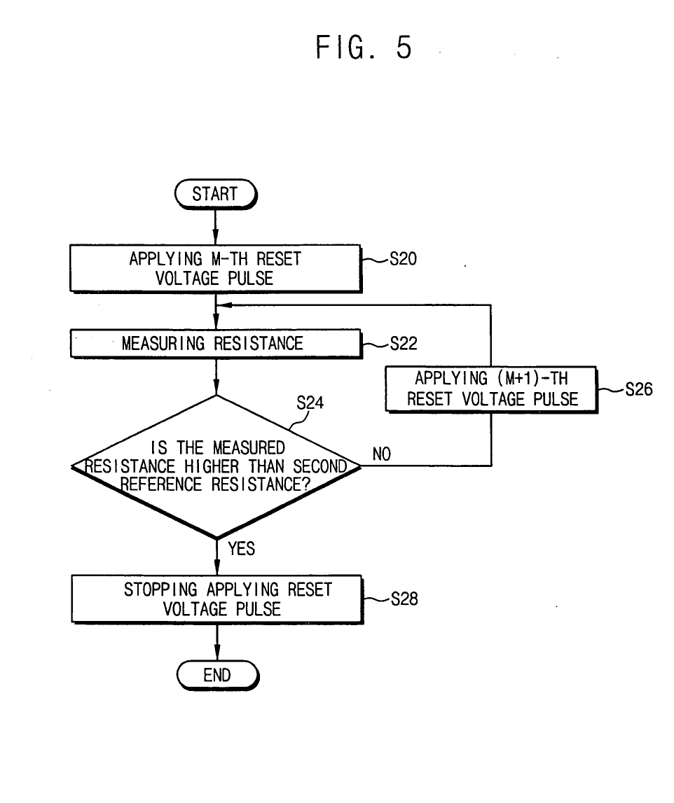

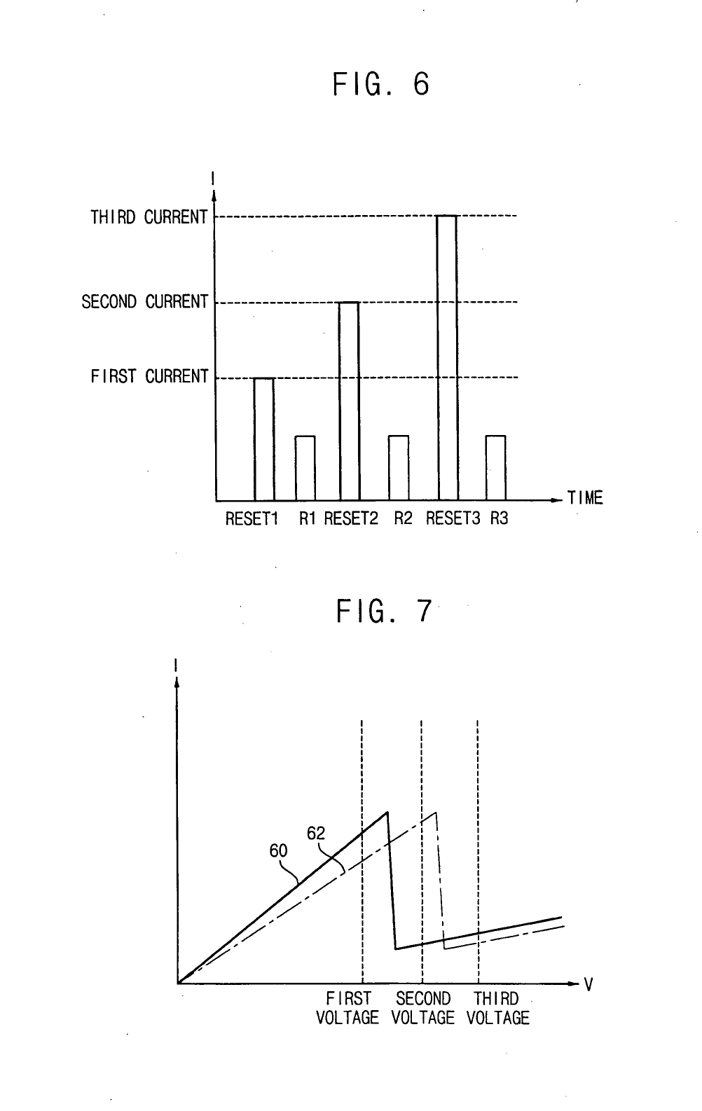

FIG. 5 is a flow chart illustrating a method of programming a reset state in a RRAM device in accordance with some embodiments of the present invention, and FIG. 6 is a timing diagram of electric pulses applied to a data storing layer pattern illustrating the method of programming the reset state in the RRAM device.

The method of programming the reset state in the unit cell of the RRAM device in FIG. 1 is illustrated with reference to FIGS. 5 and 6. Referring to FIGS. 1, 5 and 6, a first reset voltage pulse RESET1 is applied to the data storing layer pattern 14 as shown in block S20. A conductive filament may be removed from the data storing layer pattern 14 by the first reset voltage pulse RESET1.

In some embodiments of the present invention, the first reset voltage pulse RESET1 has a pulse width greater than that of the first set current voltage SET1. In some embodiments, the first reset voltage pulse RESET1 may be applied as a single pulse for about ins to about 100 ns. In some embodiments, the first reset voltage pulse RESET1 may be applied in a plurality of pulses for about 1 ns to about 100 ns.

After applying the first reset voltage pulse RESET1 to the data storing layer pattern 14, the resistance of the data storing layer pattern 14 may be measured by applying a first electric pulse R1 to the data storing layer pattern 14 so as to read resistance as shown in block S22. The first electric pulse R1 for reading resistance may include a voltage pulse and/or a current pulse. Particularly, the first electric pulse R1 for reading resistance may include a voltage pulse having a lower voltage than that of the first reset voltage pulse RESET1 or a current pulse having a low current, sufficiently low so that a set operation may not be performed.

In block S24, it is determined whether or not the measured resistance of the data storing layer pattern 14 is higher than a reference resistance of a reset state. When the measured resistance of the data storing layer pattern 14 is lower than the reference resistance, reset switching may not have been sufficiently performed. When the measured resistance of the data storing layer pattern 14 is higher than the reference resistance, reset switching may have been sufficiently performed so that the data storing layer pattern 14 may have been programmed to be in a normal reset state.

When the measured resistance of the data storing layer pattern 14 is lower than the reference resistance, a second set voltage pulse RESET2 having a voltage higher than that of the first reset voltage pulse RESET1 is applied to the data storing layer pattern 14 as shown in block S26. In block S22, the resistance of the data storing layer pattern 14 may be measured once again by applying a second electric pulse R2 to the data storing layer pattern 14 so as to read resistance.

The above-described processes are repeated until measured resistance of the data storing layer pattern 14 is higher than the reference resistance by gradually increasing voltages of reset voltage pulses. For example, as illustrated in FIG. 6, a third reset voltage pulse RESET3 having a voltage higher than that of the second reset voltage pulse RESET2 is applied to the data storing layer pattern 14. Resistance of the data storing layer pattern 14 is measured by applying a third electric pulse R3 to the data storing layer pattern 14 to thereby read resistance. When the measured resistance of the data storing layer pattern 14 is lower than the reference resistance, a fourth reset voltage pulse (not shown) having a voltage higher than that of the third reset voltage pulse RESET3 is applied to the data storing layer pattern 14. The above-mentioned processes may be repeated in such a way until measured resistance of the data storing layer pattern 14 is higher than the reference resistance.

When the measured resistance of the data storing layer pattern 14 is higher than the reference resistance, i.e., reset switching is sufficiently performed, reset voltage pulses are no longer applied to the data storing layer pattern 14 as shown in block S28. Thus, a reset state may be programmed in a unit cell of the RRAM device.

FIG. 7 is a graph showing relationships between voltages and currents of two unit cells having different critical voltage values when a reset voltage pulse is continuously applied to the unit cells by the above-described method. Referring to FIG. 7, a reset state may be programmed in the first unit cell 60 when the second reset voltage pulse RESET2 is applied, whereas the reset state may be programmed in the second unit cell 62 when the third reset voltage pulse RESET3 is applied.

As illustrated above, a reset state may be programmed in each of unit cells of a RRAM device using a minimum voltage by gradually increasing voltages of reset voltage pulses and confirming whether reset switching is sufficiently performed in each of the unit cells. As a result, the power consumption for programming the reset state in each unit cell may be reduced, and program failures and breakdown therein due to higher voltages may be limited or even prevented.

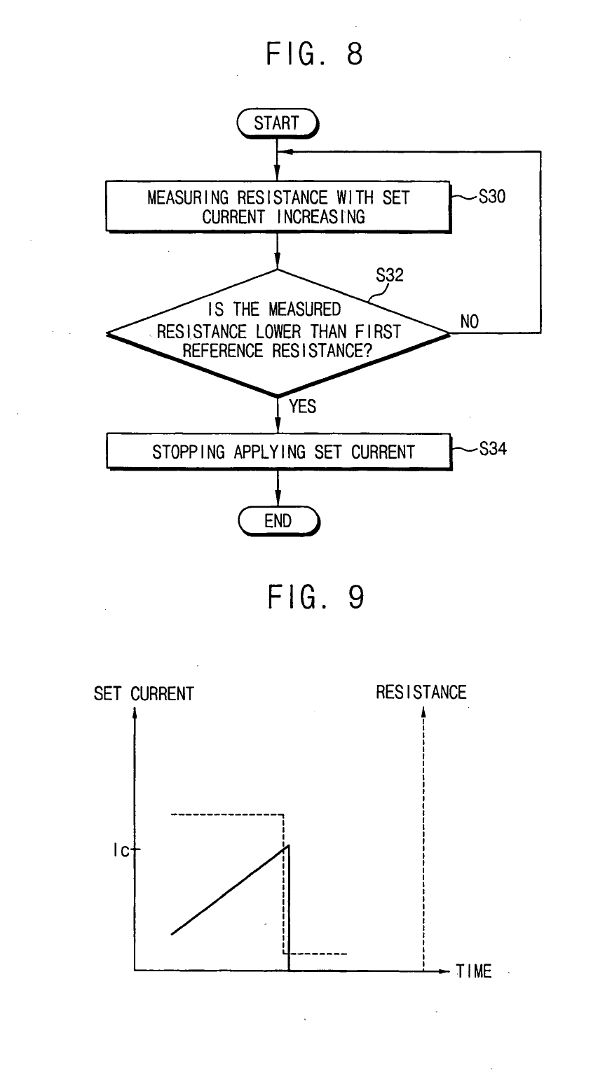

FIG. 8 is a flow chart illustrating a method of programming a set state in a RRAM device in accordance with other embodiments of the present invention. The method of programming the set state in the unit cell of the RRAM device in FIG. 1 is illustrated with reference to FIG. 8. Referring to FIGS. 1 and 8, a gradually increasing set current is applied to the data storing layer pattern 14 using the first electrode 12 or the second electrode 16 in block S30. Resistance of the data storing layer pattern 14, which is changed according to variation in the set current, is concurrently measured and monitored in block S30. The resistance of the data storing layer pattern 14 may be measured by detecting a voltage across (or at of both ends) of the data storing layer pattern 14.

In block S32, it is determined whether or not the measured resistance of the data storing layer pattern 14 is lower than a reference resistance of a set state. When the measured resistance of the data storing layer pattern 14 is lower than the reference resistance, set switching may have been sufficiently performed so that the data storing layer pattern 14 has been programmed to be in a normal set state. When the measured resistance of the data storing layer pattern 14 is lower than the reference resistance, the set current is no longer applied to the data storing layer pattern 14 as shown in block S34.

As illustrated above, a set state may be programmed in each of the unit cells of a RRAM to have substantially the same set resistance as one another by gradually increasing the current and confirming whether set switching is sufficiently performed in each of the unit cells. Such a result may be provided even when the unit cells have a wide distribution of critical current values.

The set state may be programmed in each unit cell by applying a minimum current so that a minimum amount of conductive filaments for programming the set state may be generated and that the generated conductive filaments may be more easily removed when programming a reset state.

FIG. 9 is a graph showing resistance of a data storing layer pattern when a set state is programmed in a unit cell by the above method illustrated in FIG. 8. In FIG. 9, a solid line indicates a set current applied to the data storing layer pattern over time, and the dotted line indicates the resistance of the data storing layer pattern when the set current is applied.

Referring to FIG. 9, as the set current applied to the data storing layer pattern gradually increases, the resistance rapidly drops when the set current increases to a critical current I_{c}. When the resistance rapidly drops, the set state is programmed in the unit cell. Thus, the set current is no longer applied to the data storing layer pattern after the set current is increased to the first current I_{c}.

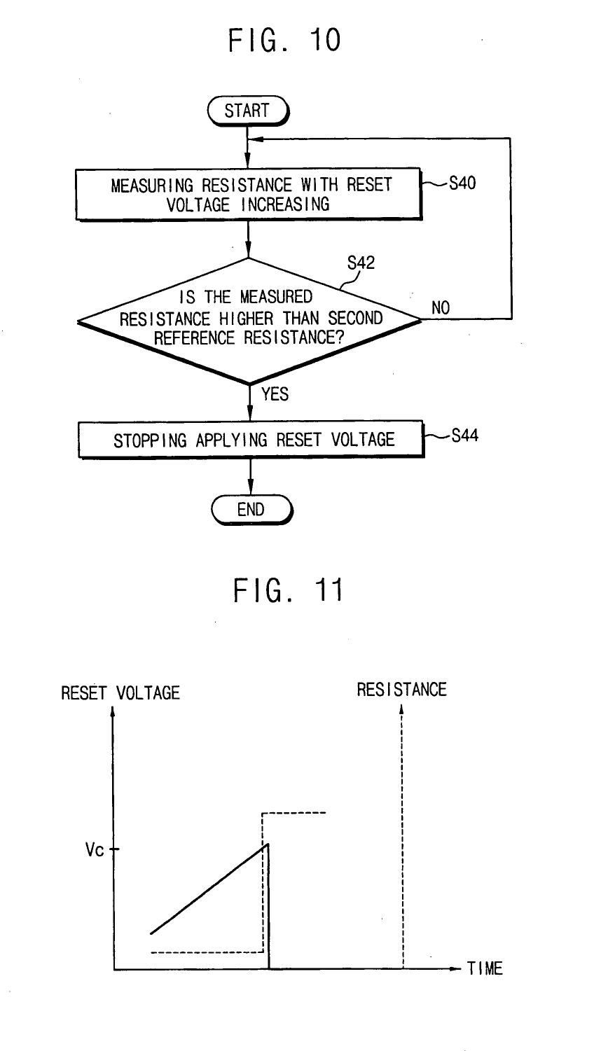

FIG. 10 is a flow chart illustrating a method of programming a reset state in a RRAM device in accordance with other embodiments of the present invention. The method of programming the reset state in the unit cell of the RRAM device in FIG. 1 is illustrated with reference to FIG. 10. Referring to FIGS. 1 and 10, a gradually increasing reset voltage is applied to the data storing layer pattern 14 as shown in block S40. Resistance of the data storing layer pattern 14, which is changed according to variation in the reset voltage, is concurrently measured and monitored. The resistance of the data storing layer pattern 14 may be measured by detecting a current flowing through the data storing layer pattern 14.

In block S42, it is determined whether or not the measured resistance of the data storing layer pattern 14 is higher than a reference resistance of a set state. When the measured resistance of the data storing layer pattern 14 is higher than the reference resistance, reset switching may have been sufficiently performed, thereby the data storing layer pattern 14 is programmed to be in a normal reset state. When the measured resistance of the data storing layer pattern 14 is higher than the reference resistance, the reset voltage is no longer applied to the data storing layer pattern 14 in block S44.

FIG. 11 is a graph showing resistance of a data storing layer pattern when a reset state is programmed in a unit cell by the above method illustrated in FIG. 10. In FIG. 11, a solid line indicates a reset voltage applied to the data storing layer pattern over time, and the dotted line indicates the resistance of the data storing layer pattern when the reset voltage is applied. Referring to FIG. 11, once the reset voltage, which is continuously applied to the data storing layer pattern, increases to a critical voltage V_{c}, the resistance rapidly increases. When the resistance is rapidly increased, the reset state is programmed in the unit cell. Thus, the reset voltage is no longer applied to the data storing layer pattern after the reset voltage is increased to the critical voltage V_{c}.

As illustrated above, the reset voltage is gradually increased and it is determined whether or not the reset state is programmed. When the reset state is programmed, the reset voltage is not applied to the data storing layer pattern so that the reset voltage may be limited or even prevented from reaching up to an unnecessarily high degree. Thus, power consumption for programming the reset state may be sufficiently reduced, and program failures and breakdown of devices due to a high voltage may be limited or even prevented.

According to some embodiments of the present invention, a set state may be programmed in each of the unit cells of a RRAM by applying a minimum current. Additionally, a reset state may be programmed in each of unit cells using a minimum voltage to remove conductive filaments from the data storing layer pattern. Thus, the conductive filaments may be substantially uniformly generated across the cells even when the unit cells have a wide distribution of critical set current values. As a result operation failures may be reduced. Furthermore, power consumption for programming the set and reset states in each unit cell may be reduced, and program failures and breakdown of devices due to a high voltage may be limited or even prevented. As a result, operation characteristics of the RRAM may be improved.

Thus, some embodiments of the present invention provide a method of programming a RRAM device in which a set state and a reset state may be programmed without generating resistance distribution of memory cells. According to some example embodiments of the present invention, a set state may be programmed in a unit cell of a RRAM device by applying a minimum current to a data storing layer pattern. Additionally, conductive filaments in the unit cell may be easily removed by applying a minimum voltage to the data storing layer pattern so that a reset state may be easily programmed. Thus, program failures and breakdown of devices due to a high voltage may be prevented.

The foregoing is illustrative of the present invention and is not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific example embodiments disclosed, and that modifications to the disclosed example embodiments, as well as other example embodiments, are intended to be included within the scope of the appended claims. The present invention is defined by the following claims, with equivalents of the claims to be included therein.

What is claimed is:

1. A method of programming a RRAM device the method comprising:
applying an increasing set current to a data storing layer pattern of the RRAM device while measuring a resistance of the data storing layer pattern until the resistance indicates a set state in the data storing layer pattern; and
applying an increasing reset voltage to the data storing layer pattern of the RRAM device while measuring the resistance of the data storing layer pattern until the resistance indicates a reset state in the data storing layer pattern.

2. The method of claim 1, wherein:
applying the increasing set current comprises repeatedly alternately applying a set current pulse and a first electric pulse, wherein the set current pulse decreases the resistance of the data storing layer pattern and the resistance of the data storing layer pattern is measured by the first electric pulse and wherein the set current pulse has an increased current each time it is applied; and
applying an increasing reset voltage comprises repeatedly alternately applying a reset voltage pulse and a second electric pulse, wherein the reset voltage pulse increases the resistance of the data storing layer pattern and the resistance of the data storing layer pattern is measured by the second electric pulse and wherein the reset voltage pulse has an increased voltage each time it is applied.

3. The method of claim 2, wherein applying the increasing set current further comprises stopping applying the set current pulse to the data storing layer pattern when the measured resistance of the data storing layer pattern is lower than a first reference resistance.

4. The method of claim 2, wherein applying the increasing reset voltage further comprises stopping applying the reset voltage pulse to the data storing layer pattern when the measured resistance of the data storing layer pattern is higher than a second reference resistance.

5. The method of claim 2, wherein the reset voltage pulse has a width greater than that of the set current pulse.

6. The method of claim 2, wherein the set current pulse comprises a plurality of pulses.

7. The method of claim 2, wherein the first and the second electric pulses comprise a current pulse and/or a voltage pulse.

8. The method of claim 2, wherein the data storing layer pattern comprises a binary metal oxide.

9. The method of claim 1, wherein:
applying the increasing set current comprises gradually increasing the set current applied to the data storing layer pattern until the resistance of the data storing layer pattern is lower than a first reference resistance; and
applying the increasing reset voltage comprises gradually decreasing the reset voltage applied to the data storing layer pattern until the resistance of the data storing layer pattern is higher than a second reference resistance.

10. The method of claim 9, wherein applying the increasing set current comprises:
measuring the resistance of the data storing layer pattern when the set current is increased, the resistance being changed responsive to the set current; and
stopping applying the set current to the data storing layer pattern when the measured resistance of the data storing layer pattern is lower than the first reference resistance.

11. The method of claim 9, wherein applying the increasing reset voltage comprises:
measuring the resistance of the data storing layer pattern when the reset voltage is increased, the resistance being changed responsive to the reset voltage; and
stopping applying the reset voltage to the data storing layer pattern when the measured resistance of the data storing layer pattern is higher than the second reference resistance.

12. The method of claim 9, wherein the resistance of the data storing layer pattern is measured by detecting a voltage of both ends of the data storing layer pattern.

13. The method of claim 9, wherein the resistance of the data storing layer pattern is measured by detecting a current flowing through the data storing layer pattern.

14. The method of claim 1, wherein:
applying the increasing set current comprises:
(a) applying an n-th set current pulse to the data storing layer pattern, the n-th set current pulse decreasing the resistance of the data storing layer pattern;
(b) determining whether the resistance of the data storing layer pattern is lower than a first reference resistance;
(c) applying a (n+1)-th set current pulse to the data storing layer pattern when the resistance of the data storing layer pattern is higher than the first reference resistance, the (n+1)-th set current pulse having a current higher than that of the n-th set current pulse;
(d) repeatedly performing steps (a) to (c) until the resistance of the data storing layer pattern is lower than the first reference resistance; and
(e) stopping applying the set current pulse to the data storing layer pattern when the resistance of the data storing layer pattern is lower than the first reference resistance; and
applying the increasing reset voltage comprises:
(f) applying an m-th reset voltage pulse to the data storing layer pattern, the m-th reset voltage pulse increasing the resistance of the data storing layer pattern;
(g) determining whether the resistance of the data storing layer pattern is higher than a second reference resistance;
(h) applying a (m+1)-th reset voltage pulse to the data storing layer pattern when the resistance of the data storing layer pattern is lower than the second reference resistance, the (m+1)-th reset voltage pulse having a voltage higher than that of the m-th reset voltage pulse;
(i) repeatedly performing steps (f) to (h) until the resistance of the data storing layer pattern is higher than the second reference resistance; and
(j) stopping applying the reset voltage pulse to the data storing layer pattern when the resistance of the data storing layer pattern is higher than the second reference resistance,
wherein n and m are positive integers.

15. The method of claim 14, further comprising applying an electric pulse for reading resistance to the data storing layer pattern, wherein the resistance of the data storing layer pattern is measured by the electric pulse for reading resistance.

16. The method of claim 1, wherein applying an increasing set current and applying an increasing reset voltage are carried out on each of a plurality of memory cells defined by a data storing layer pattern and wherein each of the respective memory cells has the set current and/or reset voltage increased to a level corresponding to a characteristic of the respective memory cell.

17. A method of programming a RRAM device, the method comprising:
programming a set state in a data storing layer pattern by alternately applying an n-th set current pulse and a first electric pulse for reading resistance, wherein the n-th set current pulse decreases resistance of the data storing layer pattern, and wherein the resistance of the data storing layer pattern is measured by the first electric pulse for reading resistance; and
programming a reset state in the data storing layer pattern by alternately applying an m-th reset voltage pulse and a second electric pulse for reading, wherein the m-th set voltage pulse increases the resistance of the data storing layer pattern, and wherein the resistance of the data storing layer pattern is measured by the second electric pulse for reading resistance,
wherein n and m are positive integers.

18. The method of claim 17, wherein when the measured resistance of the data storing layer pattern is higher than a first reference resistance, programming the set state in the data storing layer pattern further comprises:
(a) applying a (n+1)-th set current pulse to the data storing layer pattern, the (n+1)-th set current pulse configured to have a current higher than that of the n-th set current pulse;
(b) applying the first electric pulse for reading resistance to the data storing layer pattern; and
(c) repeatedly performing steps (a) and (b) until the resistance of the data storing layer pattern is lower than the first reference resistance.

19. The method of claim 18, wherein programming the reset state in the data storing layer pattern further comprises stopping applying the m-th reset voltage pulse to the data storing layer pattern when the measured resistance of the data storing layer pattern is higher than a second reference resistance.

20. The method of claim 18, wherein when the measured resistance of the data storing layer pattern is lower than a second reference resistance, programming the reset state in the data storing layer pattern further comprises:
(a) applying a (m+1)-th reset voltage pulse to the data storing layer pattern, the (m+1)-th reset voltage pulse configured to have a voltage higher than that of the m-th reset voltage pulse;
(b) applying the second electric pulse for reading resistance to the data storing layer pattern; and
(c) repeatedly performing steps (a) and (b) until the resistance of the data storing layer pattern is higher than the second reference resistance.

21. A method of programming a RRAM device, the method comprising:
programming a set state in a data storing layer pattern by gradually increasing a set current and applying the set current to the data storing layer pattern until the resistance of the data storing layer pattern is lower than a first reference resistance; and
programming a reset state in the data storing layer pattern by gradually decreasing a reset voltage and applying the reset voltage to the data storing layer pattern until the resistance of the data storing layer pattern is higher than a second reference resistance.
